(19) United States
(12) Patent Application Publication
(10) Pub. No.: US 2014/0091294 A1
(43) Pub. Date: Apr. 3, 2014

(54) Organic light-emitting diode package structure

(71) Applicant: WINTEK CORPORATION, Taichung City (TW)

(72) Inventors: Chien-Chung Chen, Taichung City (TW); Hen-Ta Kang, Taichung City (TW)

(73) Assignee: WINTEK CORPORATION, Taichung City (TW)

(21) Appl. No.: 14/043,856

(22) Filed: Oct. 2, 2013

(30) Foreign Application Priority Data
Oct. 2, 2012 (TW) 101136344

(51) Int. Cl. H01L 51/52

(52) U.S. Cl. CPC H01L 51/524
USPC 257/40

(57) ABSTRACT

An organic light-emitting diode package structure includes an organic light-emitting diode device disposed on a substrate, and a filling layer covering the organic light-emitting diode device and including a fluorine-containing polyimide layer.

### BACKGROUND OF THE INVENTION

1. Field of the Invention

The present invention relates to an organic light-emitting diode package structure, and particularly to an organic light-emitting diode package structure in which a fluorine-containing polyimide layer is utilized to encapsulate the organic light-emitting diode device.

2. Description of the Prior Art

An organic light-emitting diode device is a self-emission device, and as being characterized by being thin and lightweight, low power consumption, fast response time, and flexibility, it is widely used in illumination applications, display devices and the like. In conventional organic light-emitting diode package structures, organic light-emitting diode devices are encapsulated among two transparent substrates and a sealant. Light generated by the organic light-emitting layer of the organic light-emitting diode device may be reflected or refracted at an interface between two different materials having different refraction indexes, such that the light maybe not entirely emitted from the transparent substrate. Furthermore, since the metallic electrodes and the organic light-emitting layer of the organic light-emitting diode device are sensitive to oxygen and moisture, once the metallic electrodes and the organic light-emitting layer contact oxygen and moisture, the metallic electrodes may be oxidized and the organic light-emitting layer may peel off the metallic electrodes, resulting in a dark dot issue. The luminous efficacy and the display quality may be accordingly lowered, and the lifetime of the display device may be shortened. As a result, as the organic light-emitting diode display device is gradually developed, it is required that the encapsulation material has properties of low moisture penetration, so as to effectively isolate the organic light-emitting diode device from the outside environment, which, in turn, improves the lifetime of the organic light-emitting diode device. Therefore, there is still a need for a novel organic light-emitting diode package structure, in which the organic light-emitting diode device is effectively isolated from oxygen and moisture, having improved luminous efficacy.

### SUMMARY OF THE INVENTION

A main object of the present invention is to provide an organic light-emitting diode package structure to improve luminous efficacy and to effectively isolate the organic light-emitting diode device from oxygen and moisture.

For achieving the aforesaid object, an organic light-emitting diode package structure according to the present invention is provided. The organic light-emitting diode package structure includes a first substrate, an organic light-emitting diode device and a filling layer. The organic light-emitting diode device is disposed on the first substrate and has a light-emitting surface. The filling layer covers the light-emitting surface of the organic light-emitting diode device. The filling layer includes a fluorine-containing polyimide layer. The fluorine-containing polyimide layer includes a polymer. The polymer contains a repeating unit as represented by a chemical formula (I):

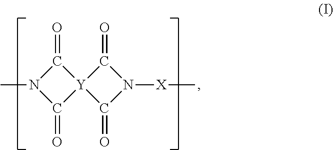

wherein X includes a moiety as represented by a chemical formula (II) or a chemical formula (III), and Y includes Ry or a moiety as represented by a chemical formula (IV):

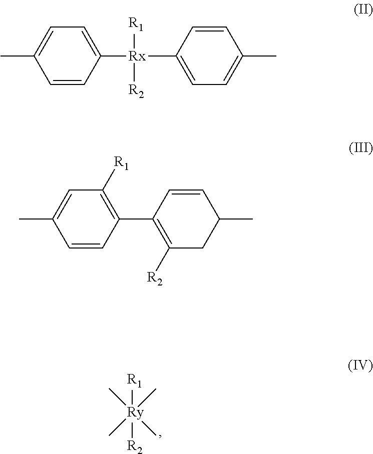

wherein Rx is one selected from carbon, an aliphatic group, and oxygen, R₁ is one selected from —H, —(CF₂)ₙ—CF₃, and —O(CF₂)ₙ—CF₃, R₂ is one selected from —H, —(CF₂)ₙ—CF₃, and —O(CF₂)ₙ—CF₃, n is an integer in a range of 0 to 11, at least one of R₁ and R₂ is a group containing fluorine element, and Ry includes an aryl group or a moiety as represented by a chemical formula (V):

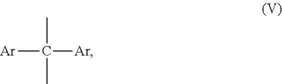

wherein Ar is an aryl group.

In the organic light-emitting diode package structure according to the present invention, a filling layer including a fluorine-containing polyimide layer is allowed to cover the organic light-emitting diode device, and the filling layer possesses both hydrophobicity and hygroscopicity. Thereby, the organic light-emitting diode device can be effectively isolated from the outside environment, and the moisture present within the organic light-emitting diode device can be absorbed. Accordingly, the deterioration of luminous efficacy of the organic light-emitting diode device affected by moisture can be avoided, and the lifetime of the organic light-emitting diode device can be increased. Furthermore, the space between the organic light-emitting diode device and the second substrate may be completely filled with the filling layer, such that the amount of total reflection of the light generated by the organic light-emitting diode device, upon passing through the interface of the filling layer and the second substrate, can be effectively reduced. Accordingly, the light extraction efficiency of the organic light-emitting diode package structure can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view illustrating an organic light-emitting diode package structure according to a first preferred embodiment of the present invention;

FIG. 2 is a schematic cross-sectional view illustrating an organic light-emitting diode package structure according to a second preferred embodiment of the present invention; and

FIG. 3 is a schematic cross-sectional view illustrating an organic light-emitting diode package structure according to a third preferred embodiment of the present invention.

### DETAILED DESCRIPTION

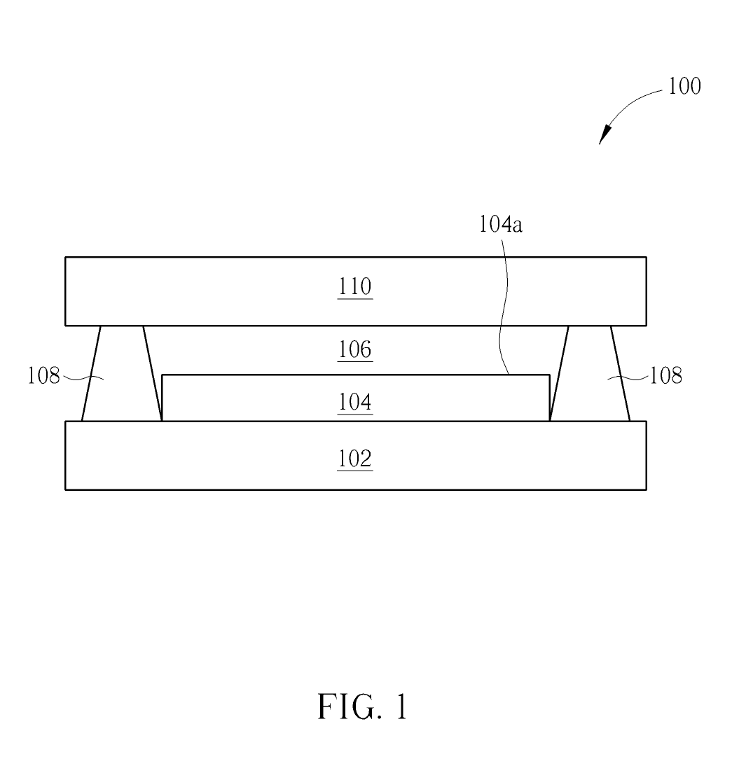

Please refer to FIG. 1. FIG. 1 is a schematic cross-sectional view illustrating an organic light-emitting diode package structure according to a first preferred embodiment of the present invention. As shown in FIG. 1, an organic light-emitting diode package structure 100 includes a first substrate 102, an organic light-emitting diode device 104, a filling layer 106, a sealing dam 108 and a second substrate 110. In this preferred embodiment, the first substrate 102 may be a transparent substrate such as glass substrate, quartz substrate, or plastic substrate, but not limited thereto. The organic light-emitting diode device 104 is disposed on the first substrate 102, and the organic light-emitting diode device 104 has a light-emitting surface 104a disposed to face up, such that the light generated by the organic light-emitting diode device 104 goes upwards. The second substrate 110 may be also a transparent substrate such as glass substrate, quartz substrate, or plastic substrate, but not limited thereto. The second substrate 110 covers the organic light-emitting diode device 104 and is disposed opposite to the first substrate 102. The sealing dam 108 is disposed between the first substrate 102 and the second substrate 110 to bond the first substrate 102 and the second substrate 110 together. The sealing dam 108 surrounds the organic light-emitting diode device 104, such that the organic light-emitting diode device 104 is encapsulated between the first substrate 102 and the second substrate 110. The filling layer 106 is filled into the space formed by the first substrate 102, the second substrate 110 and the sealing dam 108, and the portion where the organic light-emitting diode device 104 is not disposed is completely filled up. Accordingly, the filling layer 106 may cover and contact the light-emitting surface 104a of the organic light-emitting diode device 104. The filling layer 106 may further extend to the sidewall of the organic light-emitting diode device 104 to effectively encapsulate the organic light-emitting diode device 104 on the first substrate 102. In this embodiment, the thickness of the filling layer 106 is about in a range of 8 micrometers to 25 micrometers, but the present invention is not limited thereto.

It is worthy to note that, according to this preferred embodiment, the filling layer 106 is a fluorine-containing polyimide layer. Accordingly, the filling layer 106 is a transparent film, such that the light generated by the organic light-emitting diode device 104 can pass through the filling layer 106. Furthermore, the fluorine-containing polyimide layer possesses hydrophobicity due to fluorine containing, such that moisture can be prevented from entering the organic light-emitting diode device 104. Furthermore, the fluorine-containing polyimide layer possesses hygroscopicity in the same time due to polyimide containing, such that it can absorb the moisture present within the organic light-emitting diode device 104, so as to avoid the deterioration of luminous efficacy of the organic light-emitting diode device caused by the moisture and to increase the lifetime of the organic light-emitting diode device 104. In addition, the fluorine-containing polyimide layer has a relatively low birefringence due to polyimide containing, such that the light generated by the organic light-emitting diode device 104 will not be affected by different refraction indexes upon penetrating the fluorine-containing polyimide layer. Furthermore, the fluorine-containing polyimide layer further has a low dielectric constant, such that, in the case that an electronic device such as a touch panel or other is disposed on the organic light-emitting diode package structure 100, the fluorine-containing polyimide layer may effectively reduce the coupling capacitance between the organic light-emitting diode device 104 and the electronic device and lower the signal interference. Furthermore, since the fluorine-containing polyimide layer further possesses heat resistance, the quality of the fluorine-containing polyimide layer will not deteriorate when the heat is generated by the organic light-emitting diode device 104. Besides, because the fluorine-containing polyimide layer destroys the stereo-regularity of molecule chains to reduce the interaction among the molecule chains, which in turn lowers the melting point thereof, the fluorine-containing polyimide layer is a liquid-state film having soft properties. Thereby, the fluorine-containing polyimide layer may be easily filled into the space surrounded by the sealing dam 108 during the fabrication process, and help for buffering the force interaction between the second substrate 110 and the organic light-emitting diode device 104. Furthermore, in the organic light-emitting diode package structure 100 according to this embodiment, as the space between the organic light-emitting diode device 104 and the second substrate 110 the filling layer 106 is completely filled up with the filling layer 106, and the refraction index of the filling layer 106 is closer to the refraction index of the second substrate 110 than the refraction index of the air does, the amount of total refraction of the light generated by the organic light-emitting diode device 104 at the interface between the filling layer 106 and the second substrate 110 can be effectively reduced. According to a modified embodiment of the present invention, after the fluorine-containing polyimide layer is filled into the space surrounded by the sealing dam, it may be optionally solidified.

According to the embodiment, the fluorine-containing polyimide layer includes a polymer containing a repeating unit as represented by a chemical formula (I):

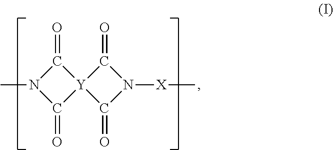

wherein, X includes a moiety represented by a chemical formula (II) or a chemical formula (III), and Y includes Ry or a moiety represented by a chemical formula (IV):

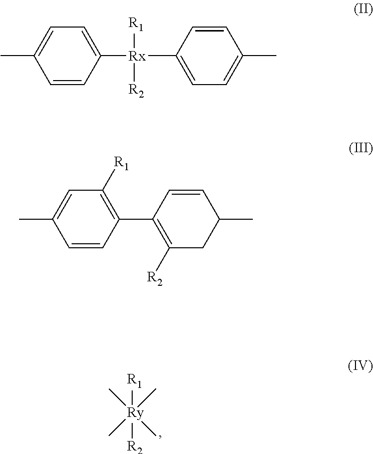

wherein, Rx is one selected from carbon, an aliphatic group, and oxygen, R₁ is one selected from —H, —(CF₂)ₙ—CF₃, and —O(CF₂)ₙ—CF₃, R₂ is one selected from —H, —(CF₂₎ₙ—CF₃, and —O(CF₂)ₙ—CF₃, n is an integer in a range of 0 to 11, at least one of R₁ and R₂ is a group containing fluorine, and Ry includes an aryl group or a moiety represented by a chemical formula (V):

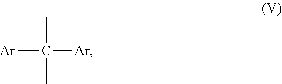

wherein, Ar is an aryl group.

Furthermore, according to this embodiment, the fluorine-containing polyimide layer may be formed by a reaction of a diamine compound and an acid dianhydride compound. At least one of the diamine compound and the acid dianhydride compound contains fluorine, such that a nondehydrated polyimide precursor produced from these two compounds may contain fluorine. The polyimide precursor is further heated to be dry or dehydrated to form the fluorine-containing polyimide layer used in this embodiment according to the present invention. When the diamine compound contains fluorine, the diamine compound may be one selected from 2,2-bis(4-aminophenyl)hexafluoropropane as represented by the chemical formula (VI),

3,3′-diamino-5,5′-bis(trifluoromethyl)biphenyl as represented by the chemical formula (VII), 4,4′-diaminooctadiphenyl ether as represented by the chemical formula (VIII), and a combination of two or more of thereof. When the acid dianhydride compound contains fluorine, the acid dianhydride compound may be one selected from 4,4′-(hexafluoroisopropylidene)bisphthalic dianhydride as represented by the chemical formula (IX),
1,4-bis(trifluoromethyl)-2,3,5,6-benzene tetracarboxylic dianhydride as represented by the chemical formula (X), and a combination of two or more of thereof:

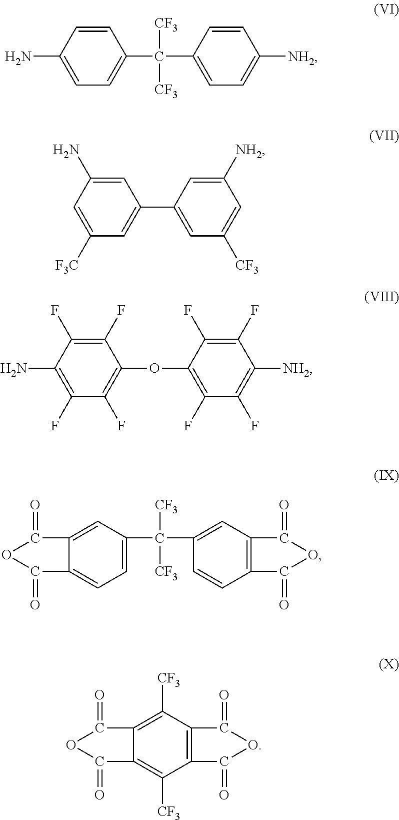 [SMILES: Nc1ccc(C(c2ccc(N)cc2)(C(F)(F)F)C(F)(F)F)cc1 ; Nc1cc(-c2cc(N)cc(C(F)(F)F)c2)cc(C(F)(F)F)c1 ; Nc1c(F)c(F)c(Oc2c(F)c(F)c(N)c(F)c2F)c(F)c1F ; O=C1OC(=O)c2cc(C(c3ccc4c(c3)C(=O)OC4=O)(C(F)(F)F)C(F)(F)F)ccc21 ; O=c1oc(=O)c2c(C(F)(F)F)c3c(=O)oc(=O)c3c(C(F)(F)F)c12]

The organic light-emitting diode package structure according to the present invention is not limited to those embodiments described above. Other embodiments or modifications according to the present invention will be further described hereinafter. For conciseness and easy comparison among the embodiments or modifications, the same elements will be denoted with the same referral numbers or symbols, and the same contents will not be described again.

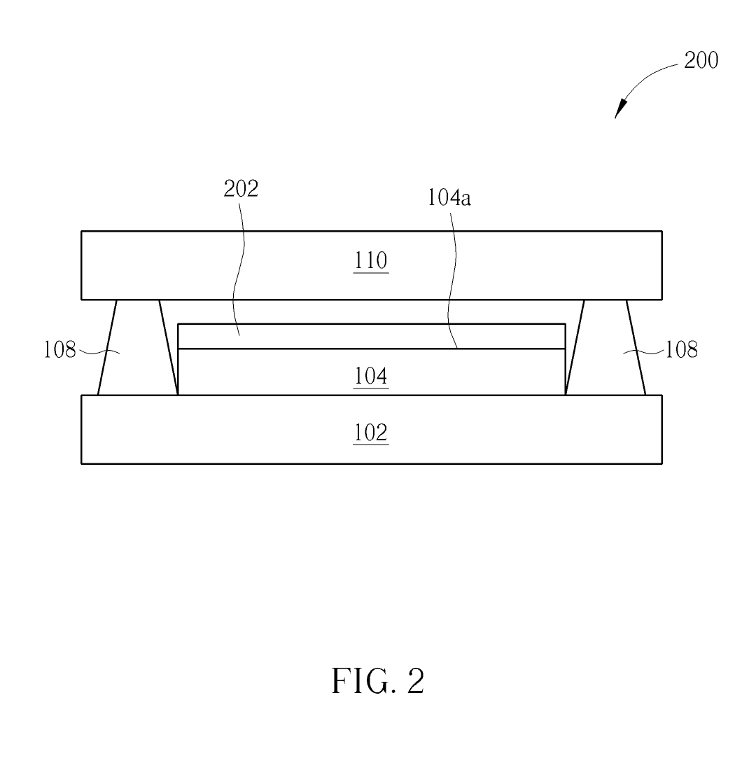

Please refer to FIG. 2. FIG. 2 is a schematic cross-sectional view illustrating an organic light-emitting diode package structure according to a second preferred embodiment of the present invention. AS shown in FIG. 2, in comparison with the first preferred embodiment, an organic light-emitting diode package structure 200 in this embodiment further includes a passivation layer 202 disposed between the filling layer 106 and the light-emitting surface 104a of the organic light-emitting diode device 104, for further protecting the organic light-emitting diode device 104. The passivation layer 202 according to this embodiment may include transparent material such as silicon oxide.

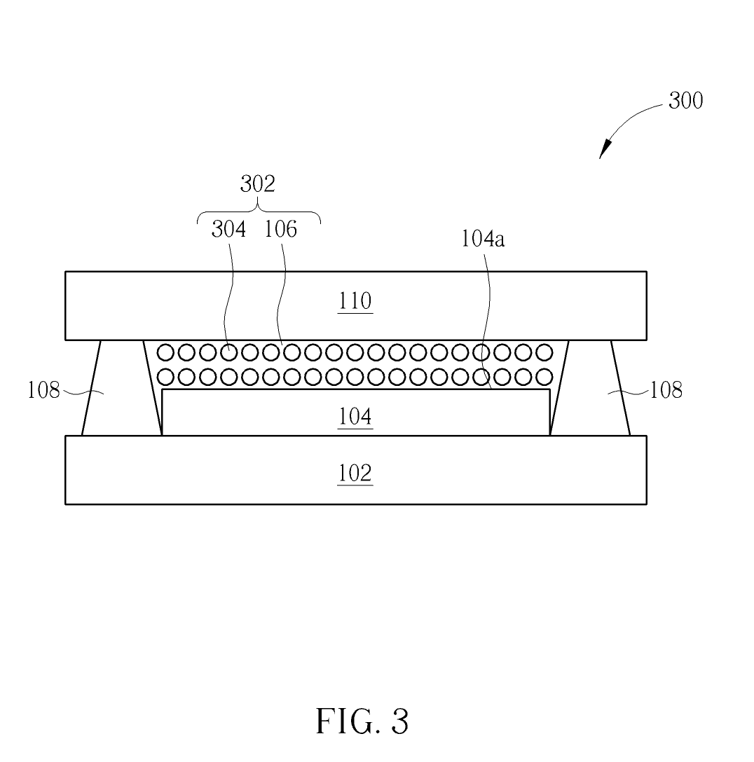

Please refer to FIG. 3. FIG. 3 is a schematic cross-sectional view illustrating an organic light-emitting diode package structure according to a third preferred embodiment of the present invention. AS shown in FIG. 3, in comparison with the first preferred embodiment, a filling layer 302 of an organic light-emitting diode package structure 300 in this embodiment further includes a plurality of scattering particles 304. The scattering particles 304 are dispersed in the fluorine-containing polyimide layer 106. According to this embodiment, the particle size of the scattering particles 304 may be in a range of 0.5 micrometers to 50 micrometers, but not limited thereto. The scattering particles 304 may be in an amount of about 0.1 to 20 by weight percent based on a total weight of the filling layer 302, but not limited thereto.

In the organic light-emitting diode package structure according to the present invention, a filling layer including a fluorine-containing polyimide layer is allowed to cover the organic light-emitting diode device, and the filling layer possess both hydrophobicity and hygroscopicity. Thereby, the organic light-emitting diode device can be effectively isolated from the outside environment, and the moisture present within the organic light-emitting diode device can be absorbed. Accordingly, the deterioration of luminous efficacy of the organic light-emitting diode device affected by the moisture can be avoided, and the lifetime of the organic light-emitting diode device can be increased. Furthermore, the filling layer maybe allowed to completely fill the space between the organic light-emitting diode device and the second substrate, such that the amount of total reflection of the light, generated by the organic light-emitting diode device, upon passing through the interface of the filling layer and the second substrate can be effectively reduced. Accordingly, the light extraction efficiency of the organic light-emitting diode package structure can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic light-emitting diode package structure, comprising:
a first substrate;
an organic light-emitting diode device disposed on the first substrate, the organic light-emitting diode device having a light-emitting surface;
a filling layer covering the light-emitting surface of the organic light-emitting diode device, the filling layer comprising a fluorine-containing polyimide layer, the fluorine-containing polyimide layer comprising a polymer containing a repeating unit represented by a chemical formula (I): 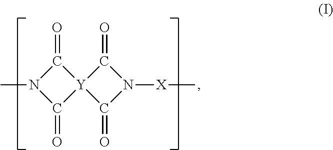
wherein, X includes a moiety represented by a chemical formula (II) or a chemical formula (III), and Y includes Ry or a moiety represented by a chemical formula (IV): 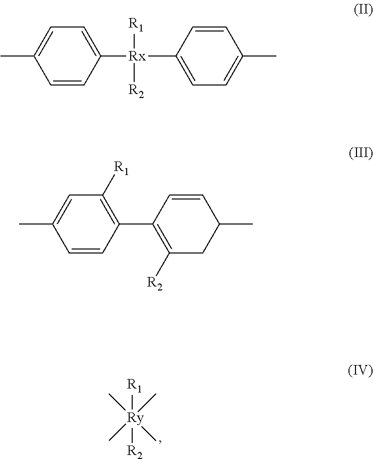
wherein, Rx is one selected from carbon, an aliphatic group, and oxygen, R₁ is one selected from —H, —(CF₂)ₙ—CF₃, and —O(CF₂₎ₙ—CF₃, R₂ is one selected from —H, —(CF₂)ₙ—CF₃, and —O(CF₂)ₙ—CF₃, n is an integer in a range of 0 to 11, at least one of R₁ and R₂ is a group containing fluorine, and Ry includes an aryl group or a moiety represented by a chemical formula (V): 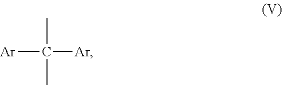
wherein, Ar is an aryl group.

2. The organic light-emitting diode package structure of claim 1, wherein, the fluorine-containing polyimide layer is formed by a reaction of a diamine compound and an acid dianhydride compound.

3. The organic light-emitting diode package structure of claim 2, wherein, the diamine compound is one selected from 2,2-bis(4-aminophenyl)hexafluoropropane, 3,3′-diamino-5,5′-bis(trifluoromethyl)biphenyl, and 4,4′-diaminooctadiphenyl ether.

4. The organic light-emitting diode package structure of claim 2, wherein, the acid dianhydride compound is one selected from 4,4′-(hexafluoroisopropylidene)bisphthalic dianhydride and 1,4-bis(trifluoromethyl)-2,3,5,6-benzene tetracarboxylic dianhydride.

5. The organic light-emitting diode package structure of claim 1, further comprising:
a second substrate disposed opposite to the second substrate; and
a sealing dam disposed between the first substrate and the second substrate to bond the first substrate and the second substrate together, the sealing dam surrounding the organic light-emitting diode device.

6. The organic light-emitting diode package structure of claim 1, further comprising a passivation layer disposed between the filling layer and the organic light-emitting diode device.

7. The organic light-emitting diode package structure of claim 1, wherein the filling layer further comprises a plurality of scattering particles dispersed in the fluorine-containing polyimide layer.

8. The organic light-emitting diode package structure of claim 7, wherein each of the scattering particles comprises silicon dioxide, titanium dioxide, zirconium dioxide, or aluminum oxide.

9. The organic light-emitting diode package structure of claim 1, wherein the fluorine-containing polyimide layer is a liquid-state film.
